(19) United States
(12) Patent Application Publication
(10) Pub. No.: US 2025/0087520 A1
(43) Pub. Date: Mar. 13, 2025

(54) CARRIER TAPE

(71) Applicant: Renesas Electronics Corporation, Tokyo (JP)

(72) Inventor: Kouji NAKAJIMA, Tokyo (JP)

(21) Appl. No.: 18/773,673

(22) Filed: Jul. 16, 2024

(30) Foreign Application Priority Data
Sep. 7, 2023 (JP) 2023-144911

(51) Int. Cl. H01L 21/683

(52) U.S. Cl. CPC H01L 21/6836; H01L 2221/68309; H01L 2221/68313

(57) ABSTRACT

A carrier tape includes a first layer component having a recess and a first opening in a center of the recess, and a second layer component housed in the recess, the second layer having a center arranged parallel to the recess, a step part arranged around the center by a step falling from the center, a second opening overlapping the first opening arranged in the center, and a third opening arranged in the step part.

### CROSS-REFERENCE TO RELATED APPLICATIONS

The disclosure of Japanese Patent Application No. 2023-144911 filed on Sep. 7, 2023, including the specification, drawings and abstract is incorporated herein by reference in its entirety.

### BACKGROUND

The present invention relates to a carrier tape. A carrier tape has been developed as a packaging material for protecting and transporting semiconductor devices. Patent Document 1 discloses a carrier tape equipped with a carrier tape body, which is formed by arranging multiple pockets for storing QFP ICs, each of which has multiple outer leads protruding from sides of the resin sealing body, in an adjacent manner with a connecting part in between. A guide that engages with the corner of the resin sealing body of the QFP ICs is formed in the corner of the pocket of the carrier tape body.

### PRIOR ART DOCUMENT

### Patent Document

[Patent Document 1] Japanese Unexamined Publication Laid-Open No. 10-287387

### SUMMARY

However, the carrier tape of Patent Document 1 has a risk of causing product defects due to metal debris produced when burrs of the outer leads come into contact with the carrier tape body. Therefore, the purpose of this disclosure is to provide a carrier tape that prevents product defects caused by debris falling off the product.

Other problems and novel features will become apparent from the description and accompanying drawings of this specification.

According to one embodiment, a carrier tape includes a first layer component having a recess and a first opening in a center of the recess, and a second layer component housed in the recess, the second layer having a center arranged parallel to the recess, a step part arranged around the center by a step falling from the center, a second opening overlapping the first opening arranged in the center, and a third opening arranged in the step part.

According to the above embodiment, debris can be sealed between the component of the first layer and the component of the second layer, preventing the product and debris from coming into contact.

### BRIEF DESCRIPTION OF THE DRAWINGS

FIG. 1 is a schematic diagram showing a top view and a cross-sectional view of the carrier tape and a product according to a first embodiment.

FIG. 2 is a schematic diagram showing a top view and a cross-sectional view of the carrier tape, a product and its burrs according to the first embodiment.

FIG. 3 is an exploded view of the components of the first layer and the second layer of the carrier tape according to the first embodiment.

FIG. 4 is a top view and a cross-sectional view of the carrier tape according to a second embodiment.

FIG. 5 is a top view and a cross-sectional view of the carrier tape according to a third embodiment.

FIG. 6 is a schematic perspective view showing a top view and a cross-sectional view of a related carrier tape, and the related carrier tape and a product.

FIG. 7 is a schematic diagram showing a cross-sectional view of the related carrier tape, and the product and its burrs.

FIG. 8 is a schematic perspective view showing a top view and a cross-sectional view of another related carrier tape, and the related carrier tape and a product.

### DETAILED DESCRIPTION

For clarity of explanation, the following description and drawings are appropriately omitted and simplified. In each drawing, the same elements are given the same reference numerals, and redundant explanations are omitted as necessary.

### First Embodiment

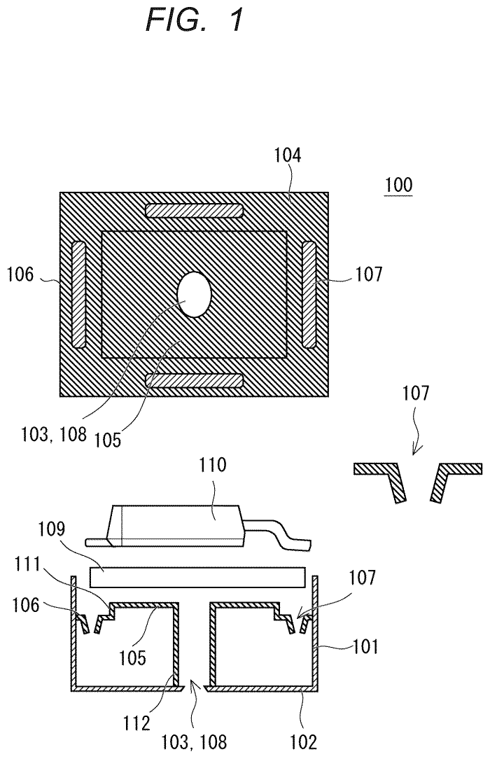

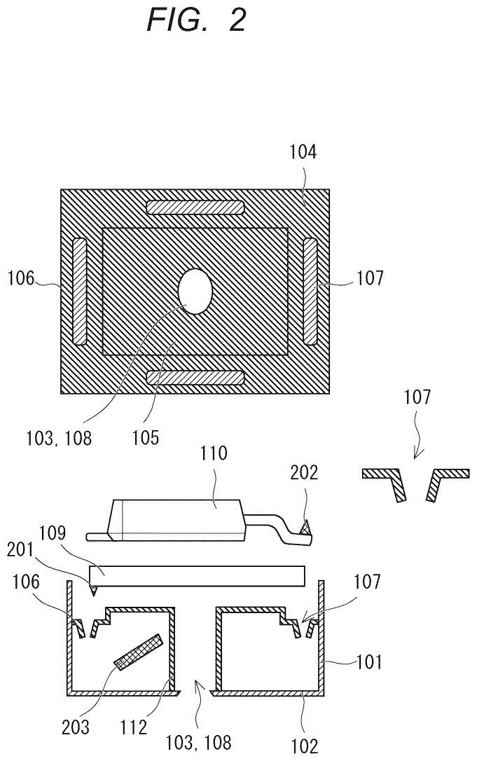

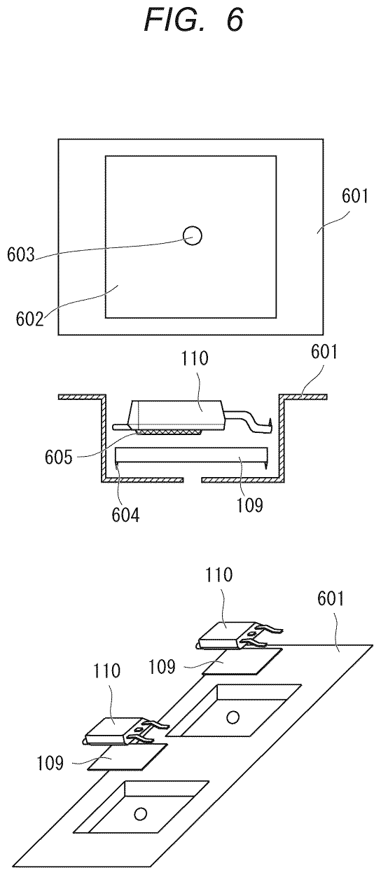

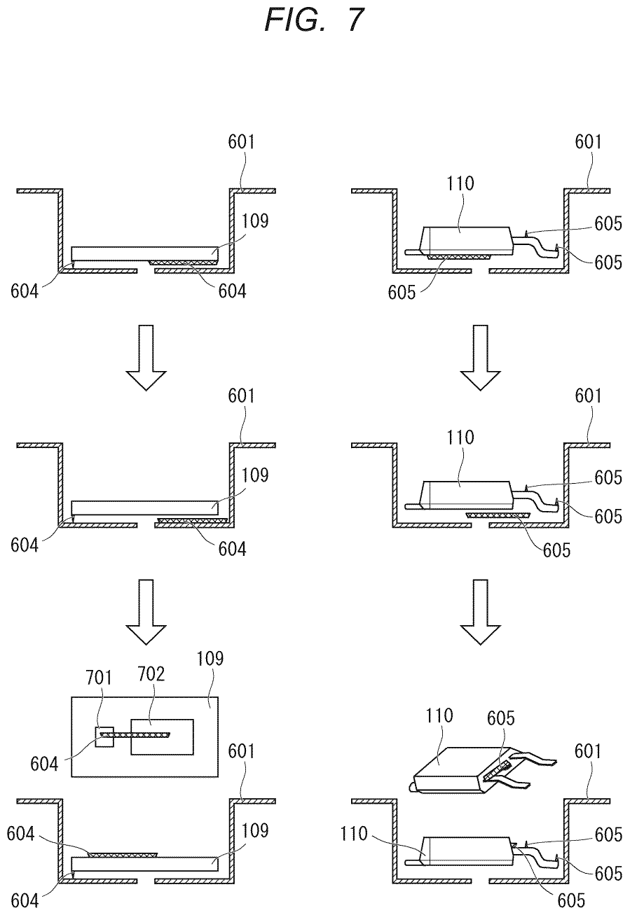

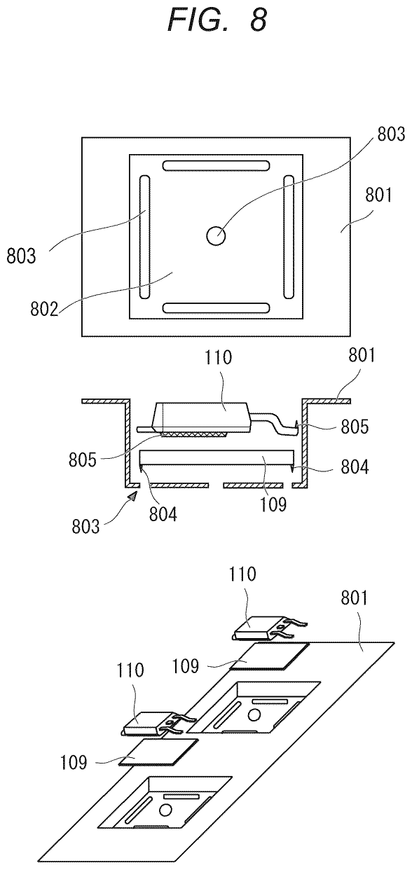

FIG. 1 is a schematic diagram showing a top view and a cross-sectional view of a carrier tape and a product according to the first embodiment. FIG. 2 is a schematic diagram showing a top view and a cross-sectional view of the carrier tape, and the product and its burrs according to the first embodiment. FIG. 6 is a schematic perspective view showing a top view and a cross-sectional view of a related carrier tape, and the related carrier tape and a product. FIG. 7 is a schematic diagram showing a cross-sectional view of the related carrier tape, and the product and its burrs. FIG. 8 is a schematic perspective view showing a top view and a cross-sectional view of another related carrier tape, and the related carrier tape and a product. The carrier tape according to the first embodiment will be described with reference to FIGS. 1, 2, and 6 to 8.

As shown in the upper diagram of FIG. 6, the related carrier tape 601 is equipped with a recess 602 and an opening 603.

As shown in the middle diagram of FIG. 6, products such as semiconductor chip 109 or semiconductor package 110 are stored in the recess 602. The products have burr 604 of the semiconductor chip 109 and burr 605 of the semiconductor package 110. The opening 603 is formed to vacuum-draw the product into the recess 602.

As shown in the lower diagram of FIG. 6, by forming these recesses 602 continuously on the related carrier tape 601, multiple products are stored on the related carrier tape 601. The related carrier tape 601 storing the products is wound on a reel and transported.

As shown in the upper left diagram of FIG. 7, the burr 604 of the semiconductor chip 109 contacts the related carrier tape 601. As shown in the middle-left diagram of FIG. 7, a part of the burr 604 falls off from the semiconductor chip 109. As shown in the lower left diagram of FIG. 7, the fallen burr 604 may short-circuit between electrodes 701 and 702. Therefore, the related carrier tape 601 may cause product defects.

As shown in the upper right diagram of FIG. 7, the burr 605 of the semiconductor package 110 contacts the related carrier tape 601. As shown in the middle right diagram of FIG. 7, a part of the burr 605 falls off from the semiconductor package 110. As shown in the lower right diagram of FIG. 7, the fallen burr 605 may short-circuit between the terminals of the semiconductor package. Therefore, the related carrier tape 601 may cause product defects.

As shown in the upper diagram of FIG. 8, it is conceivable to provide other openings 803 in the recess 802 of the related carrier tape 801. As shown in the middle diagram of FIG. 8, the burrs 804 of the semiconductor chip 109 and the burr 805 of the semiconductor package 110 can exit from the opening 803 to the outside of the carrier tape 801. However, the moisture retention in the carrier tape 801 deteriorates. Also, it becomes easier for dirt from the outside to enter the carrier tape 801.

Therefore, as shown in FIG. 1, a carrier tape 100 according to the embodiment has a two-layer structure comprising a first layer component 101 and a second layer component 104. The first layer component 101 has a recess 102 and a first opening 103. The second layer component 104 has a center part 105 arranged parallel to the recess 102 and a step part 106 arranged around the center part 105 by a step 111 falling downward from the center part 105. Also, the second layer component 104 has a second opening 108 overlapping the first opening 103 arranged in the center part 105, and a third opening 107 arranged in the step part 106.

The recess 102 is provided to match the shape of product such as a semiconductor chip 109 or a semiconductor package 110. For example, the recess 102 is square or rectangular in plan view. Also, it may be a rectangle that extends to fit the product and terminals of the product. There is no limitation on the shape of the recess 102, and it may be circular or elliptical.

The depth of the recess 102 is preferably deep enough to make a double bottom using the second layer component 104 and shallow enough to be able to wind a lot on a reel.

The first opening 103 is a ventilation port for vacuum suction of the product. The first opening 103 is provided at the center of the recess 102. The first opening 103 is preferably circular or elliptical. The first opening 103 is preferably not as large as the product and is of a size that allows ventilation.

The center part 105 is a shape that is one size smaller than the shape of the recess 102. The center part 105 is made to a certain size to match the product because it carries the product. Also, it is preferable to make the center part 105 parallel to the recess 102 to prevent the product from deviating. The center part 105 has a second opening 108 and does not interfere with the vacuum suction from the first opening 103.

The second opening 108 is preferably of the same shape as the first opening 103, such as circular or elliptical. A tubular component 112 is provided under the second opening 108. The second opening 108 has a larger outer circumference than the first opening 103, and by supporting the tubular component 112, the second layer component 104 can maintain a certain height relative to the first layer component 101.

The step portion 106 is located one step lower due to the step 111. Therefore, when a product is placed on the center part 105, it is ensured that the terminals of the product do not touch the bottom surface of the step portion 106. This makes it less likely for debris caused by burrs to occur. Also, when the recess 102 is rectangular, it is preferable that the step portion 106 is arranged in a rectangle along the outer circumference of the rectangular recess. If the recess is not rectangular, it is preferable that the step portion 106 is arranged along the outer circumference of the recess.

Also, the step portion 106 is equipped with a third opening 107. As shown in the middle figure of FIG. 1, the third opening 107 is equipped with a return. The return may be formed by a part that is removed to form the opening when making the opening. The third opening 107 is preferably arranged in a shape that combines a rectangle, a rectangle with rounded corners, an ellipse, or two semicircles and a rectangle, along the outer circumference of the recess. Also, considering the short circuit between terminals, the length of the third opening is preferably 200 um or more.

As shown in FIG. 2, suppose that the burr 201 of the semiconductor chip 109 and the burr 202 of the semiconductor package 110 have peeled off and created debris 203. As shown in the lower figure of FIG. 2, the carrier tape 100 according to the embodiment can trap the debris 203 in the third opening 107, between the first layer component 101 and the second layer component 104. Therefore, it is possible to prevent the debris 203 from touching the terminal part of the product and causing a defect. Also, by the two-layer structure, it is possible to maintain the humidity inside the carrier tape 100 and prevent the generation of static electricity. Also, the two-layer structure can prevent the intrusion of debris from the outside.

### (Implementation Example of Carrier Tape According to the First Embodiment)

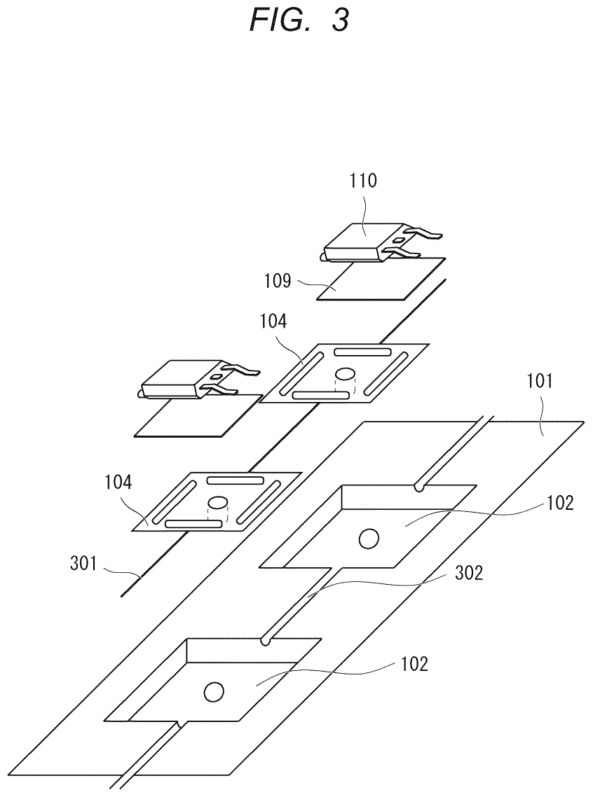

FIG. 3 is an exploded view of the first layer component and the second layer component of the carrier tape according to the first embodiment. Referring to FIG. 3, an implementation example of the carrier tape according to the first embodiment will be explained.

As shown in FIG. 3, the carrier tape 100 is a long tape-shaped first layer component 101 that extends in one direction for winding on a reel. The first layer component 101 has multiple recesses 102. A linear recess 302 extending linearly is connected between the recesses 102.

The second layer component 104 exists in multiple numbers so as to be fitted into the multiple recesses 102. A linear guide part 301 is connected between the second layer components 104. The guide part 301 fits into the linear recess 302 extending linearly. In this way, multiple second layer components 104 that fit into the multiple recesses 102 are provided. Multiple semiconductor chips 109 or semiconductor packages 110 are stored in the multiple recesses 102 and the multiple second layer components 104.

A manufacturing method of this carrier tape will be explained. First, the first layer component 101 is formed using a mold. Then, the second layer component 104 is formed with another mold. At this time, the guide part 301 is also formed. Then, a groove is provided in the center part of the first layer component 101 so that the second layer component 104 can be accurately and easily accommodated in the recess 102 of the first layer component 101, the recess 302 is formed, and the guide part 301 of the second layer component is fitted. Finally, the first layer component 101 and the second layer component 104 are overlapped, and the product is stored in the recess 102.

### Second Embodiment

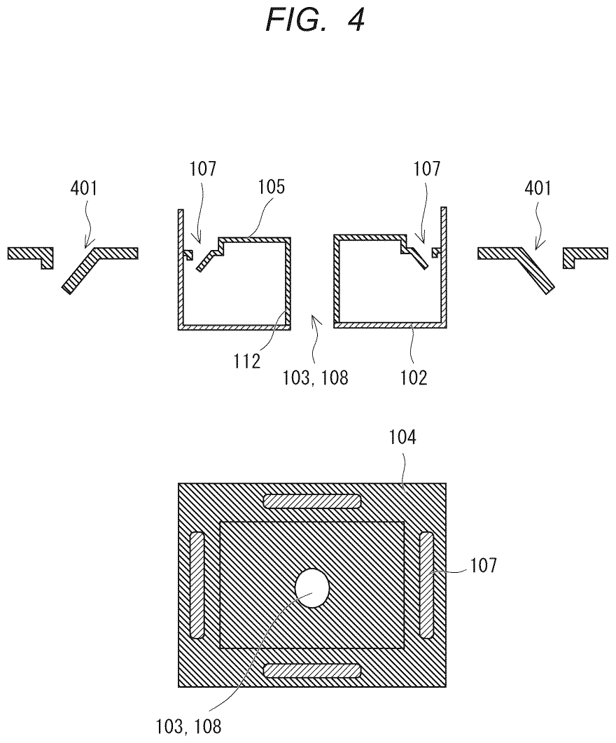

FIG. 4 is a top view and a cross-sectional view of a carrier tape according to the second embodiment.

As shown in FIG. 4, a return 401 is formed in the third opening 107. The return 401 is directed outward from the center 105. In other words, the return 401 is attached from the inside to the outside of the second layer component 104. By doing so, the dust that was attached to the semiconductor chip 109 (or semiconductor package 110) can be trapped in the space composed of the first layer component 101 and the second layer component 104. The presence of the return prevents the trapped dust from reattaching to the semiconductor chip 109 (or semiconductor package 110).

### Third Embodiment

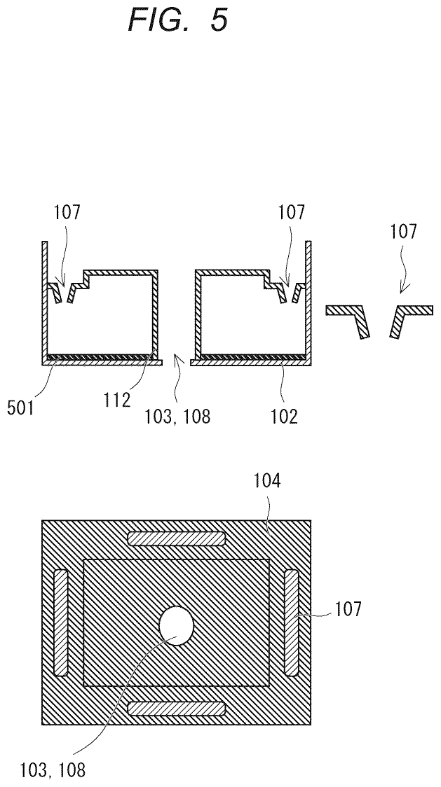

FIG. 5 is a top view and a cross-sectional view of a carrier tape according to the third embodiment.

As shown in FIG. 5, the carrier tape according to the third embodiment has an adhesive 501 applied to the bottom surface of the recess 102. By doing so, the dust that was attached to the semiconductor chip 109 (or semiconductor package 110) can be trapped in the space composed of the first layer component 101 and the second layer component 104. The presence of the adhesive 501 allows the trapped dust to adhere to the adhesive 501, thereby preventing it from reattaching to the semiconductor chip 109 (or semiconductor package 110).

The invention made by the present inventor has been specifically described based on the embodiments, but it goes without saying that the present invention is not limited to the embodiments described above and various changes can be made within the scope not departing from the gist thereof.

What is claimed is:

1. A carrier tape comprising:
a first layer component having a recess and a first opening in a center of the recess; and
a second layer component housed in the recess, the second layer having a center arranged parallel to the recess, a step part arranged around the center by a step falling from the center, a second opening overlapping the first opening arranged in the center, and a third opening arranged in the step part.

2. The carrier tape according to claim 1, wherein the recess is rectangular.

3. The carrier tape according to claim 2, wherein the step part is arranged along the outer periphery of the rectangular recess.

4. The carrier tape according to claim 2, wherein the third opening is arranged in a shape of a rectangle, a rectangle with rounded corners, an ellipse, or a combination of two semicircles and a rectangle along the outer periphery of the rectangular recess.

5. The carrier tape according to claim 1, wherein the second opening has a larger outer periphery than the first opening.

6. The carrier tape according to claim 1, wherein the second opening has a return.

7. The carrier tape according to claim 6, wherein the return is attached from the inside to the outer periphery of the second layer component.

8. The carrier tape according to claim 1, wherein an adhesive is applied to a bottom surface of the recess of the first layer.

9. The carrier tape according to claim 1,
wherein the recess has a plurality of recesses,
wherein the second layer component has a plurality of layer components,
wherein a guide part is connected between the plurality of layer components,
wherein a recess that fits into the guide section between the plurality of recesses, and
wherein the first layer component has a linear recess fitting between the plurality of recesses.
